(19) United States
(12) Patent Application Publication
(10) Pub. No.: US 2017/0196100 A1
(43) Pub. Date: Jul. 6, 2017

(54) BEZEL OF DISPLAY DEVICE AND MANUFACTURING METHOD THEREOF

(71) Applicants: Le Holdings (Beijing) Co., Ltd., Beijing (CN); LE SHI ZHI XIN ELECTRONIC TECHNOLOGY (TIANJIN) LIMITED, Tianjin (CN)

(72) Inventor: Ke HUANG, Tianjin (CN)

(21) Appl. No.: 15/250,661

(22) Filed: Aug. 29, 2016

Related U.S. Application Data
(63) Continuation of application No. PCT/CN2016/088192, filed on Jul. 1, 2016.

(30) Foreign Application Priority Data
Dec. 30, 2015 (CN) 201511030446.X

(51) Int. Cl. H05K 5/00; H05K 5/02; B21D 11/20; H05K 5/04

(52) U.S. Cl. CPC H05K 5/0017; H05K 5/04; H05K 5/02; B21D 11/20

(57) ABSTRACT

Disclosed are a bezel of a display device and a manufacturing method thereof are provided, where the bezel is a 90-degree bezel without gaps at front and rear surfaces, which is formed by an aluminum extruded profile with a U-shaped cross-section which is softened under a high temperature and bent by using a bending mold. The method includes: softening an aluminum extruded profile with a U-shaped cross-section under a high temperature; and bending the aluminum extruded profile with a U-shaped cross-section using a bending mold to form a 90-degree bezel without gaps at front and rear surfaces.

### CROSS REFERENCE TO RELATED APPLICATIONS

This application is a continuation of International Application No. PCT/CN2016/088192, filed on Jul. 1, 2016, which is based upon and claims priority to Chinese Patent Application No. 201511031434.9, filed on Dec. 30, 2015, the entire contents of which are incorporated herein by reference.

### TECHNICAL FIELD

The disclosure relates to the technical field of display devices, and more particularly, to a bezel of a display device and a method for manufacturing the same.

### BACKGROUND

With the improvement of people's living standards, electrical appliances used by people have transformed from original functional ones to those with slightly appearance. Further, people are imposing higher and higher requirements on video watching devices such as televisions.

The frame of a display device such as a television is generally made by splicing four profile strips at the four edges. The splicing method at the four edges results in gaps at the front and rear surfaces of the bezel, which seriously impairs the appearance of the display device.

Therefore, it is a technical problem to be urgently solved as how to provide a more sightly bezel of a display device.

### SUMMARY

In view of the above, the present application provides a bezel of a display device and a manufacturing method thereof, which can eliminate the gaps at front and rear surfaces of a BEZEL to improve the appearance of the bezel.

The present application provides a bezel of a display device, where the bezel is a 90-degree bezel without gaps at front and rear surfaces, which is formed by an aluminum extruded profile with a U-shaped cross-section which is softened under a high temperature and bent by using a bending mold.

The present application further provides a display device, including a bezel and a display module, and the bezel being used to fix the display module,

the bezel is a 90-degree bezel without gaps at front and rear surfaces, which is formed by an aluminum extruded profile with a U-shaped cross-section which is softened under a high temperature and bent by using a bending mold.

The present application further provides a method for manufacturing a bezel of a display device, the bezel being used to fix a display module of the display device, including

softening an aluminum extruded profile with a U-shaped cross-section under a high temperature; and

bending the aluminum extruded profile with a U-shaped cross-section using a bending mold to form a 90-degree bezel without gaps at front and rear surfaces.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is an installation schematic diagram of a bezel and a display module according to the present application;

FIG. 2 is a schematic diagram of a bezel of a display device according to the present application;

FIG. 3 is a cross-sectional schematic diagram of a bezel of a display device according to the present application;

FIG. 4a to FIG. 4d are schematic diagrams illustrating states of manufacturing a bezel of a display device according to the present application; and

FIG. 5 is a flowchart of a method for manufacturing a bezel of a display device according to the present application.

### DETAILED DESCRIPTION

A BEZEL according to the present application is a 90-degree bezel without gaps at front and rear surfaces, which is formed by an aluminum extruded profile with a U-shaped cross-section which is softened under a high temperature and bent by using a bending mold. Therefore, in the present application, the bezel that is formed by bending the aluminum extruded profile by making use of its characteristics has no gap at front and rear surfaces. As a result, the bezel of a display device manufactured according to the present application keeps the appearance of display device being impaired by gaps at the front and rear surfaces of the bezel, and improves the appearance of the display device.

Nevertheless, it is not necessary to require that practice of any technical solution of the present application achieves all of the above technical effects.

To make a person skilled in the art better understand the technical solutions of embodiments of the present application, the technical solutions of the present application are clearly and completely described with reference to the accompanying drawings of the embodiments of the present application. Apparently, the described embodiments are only a part of embodiments of the present application, rather than the entire embodiments. Based on the embodiments of the present application, all other embodiments derived by persons of ordinary skill in the art shall fall within the protection scope of the present application.

The following further describes specific implementations of the present application with reference to drawings of the present application.

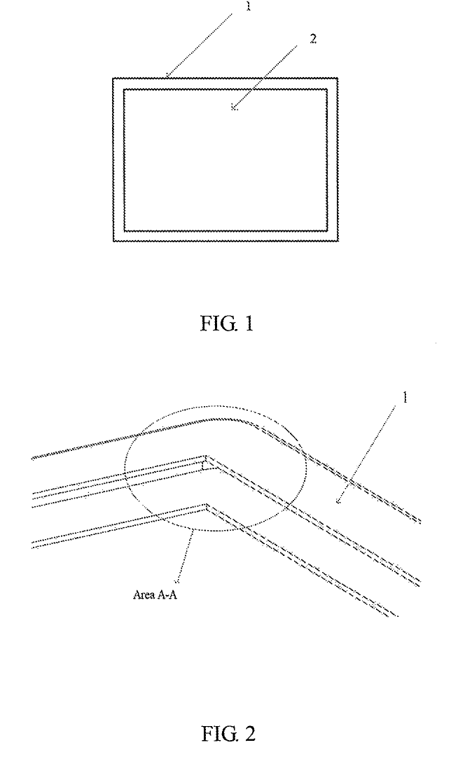

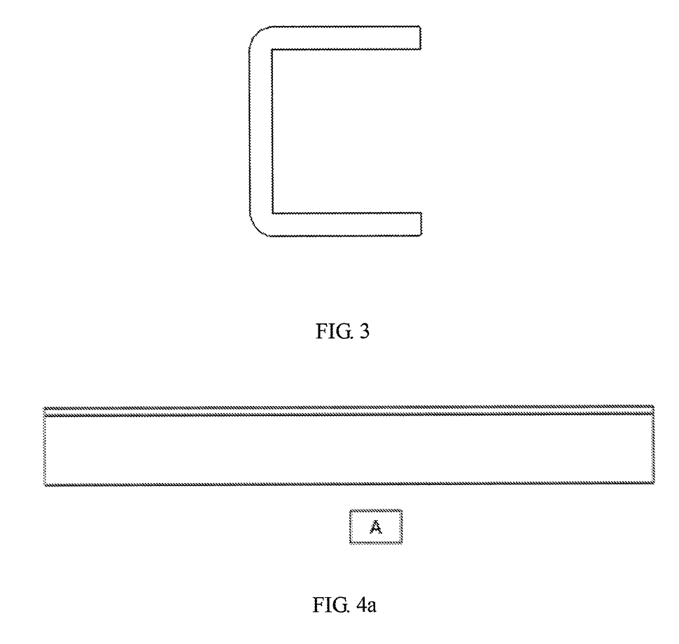

Referring to FIG. 1, a specific embodiment of the present application provides a bezel 1 of a display device, the bezel 1 being used to fix a display module 2 of the display device.

Referring to FIG. 2, the bezel 1 is a 90-degree bezel without gaps at front and rear surfaces, which is formed by an aluminum extruded profile with a U-shaped cross-section which is softened under a high temperature and bent by using a bending mold (area A-A in the figure).

The bezel of the display device manufactured according to the present application keeps the appearance of display device being impaired by gaps at the front and rear surfaces of the bezel, and improves the appearance of the display device.

In another specific implementation of the present application, in order to bend the aluminum extruded profile more smoothly, the bending mold bends the aluminum extruded profile from 180 degrees to 90 degrees through N bending angles in order, the N bending angles being less than 180 degrees and greater than 90 degrees.

The N may be selected by a person skilled in the art according to requirements, and the bending angles gradually approach 90 degrees from 180 degrees.

Specifically, the N is two, and the bending angles include a first bending angle and a second bending angle.

The first bending angle is 150 degrees, and the second bending angle is 120 degrees.

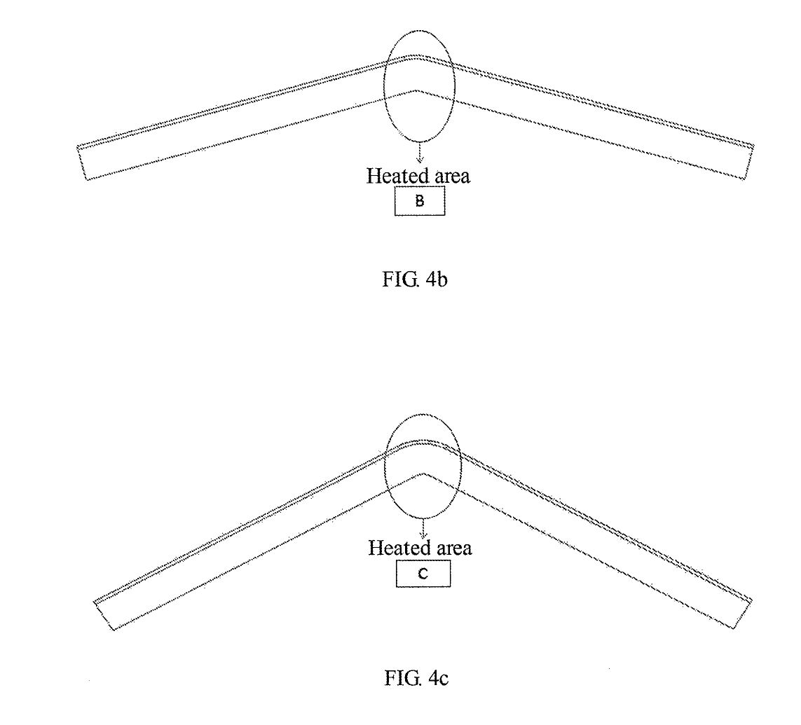

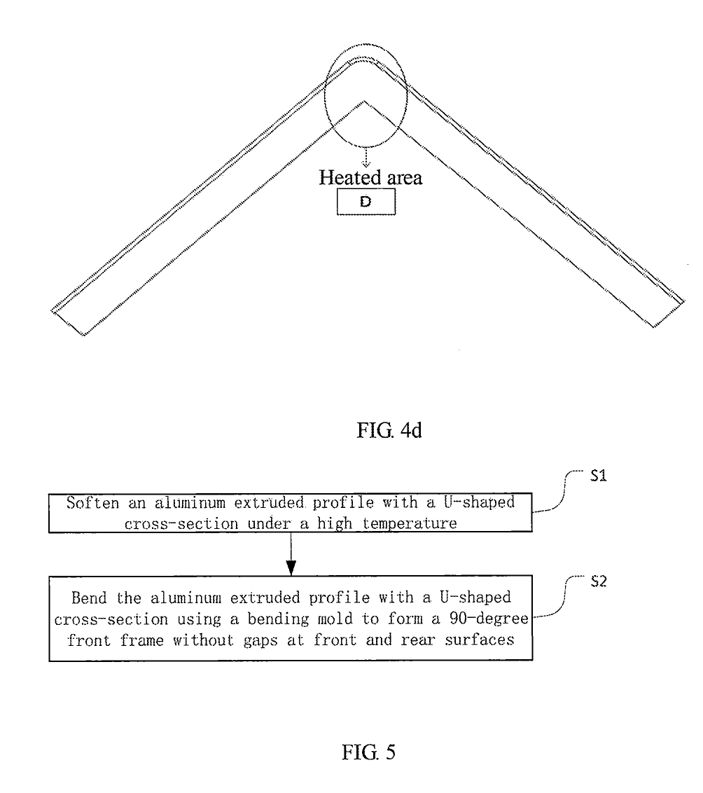

Referring to FIG. 4a, an area A of the aluminum extruded profile is heated.

Referring to FIG. 4b, an area B of the aluminum extruded profile is heated, a crack arrest groove 41 is slotted at the rear of the aluminum extruded profile, and a bending angle of the aluminum extruded profile is made to be 140 degrees by using the bending mold.

Referring to FIG. 4c, an area C of the aluminum extruded profile is heated, and the bending angle of the aluminum extruded profile is made to be 120 degrees by using the bending mold.

Referring to FIG. 4d, an area D of the aluminum extruded profile is heated, and the bending angle of the aluminum extruded profile is made to be 90 degrees by using the bending mold.

Referring to FIG. 1, another specific embodiment of the present application provides a display device, the display device including a bezel 1 and a display module 2, and the bezel 1 being used to fix a display module 2 of the display device.

Referring to FIG. 2, the bezel 1 is a 90-degree bezel without gaps at front and rear surfaces, which is formed by an aluminum extruded profile with a U-shaped cross-section which is softened under a high temperature and bent by using a bending mold (area A-A in the figure).

The bezel of the display device manufactured according to the present application keeps the appearance of display device being impaired by gaps at the front and rear surfaces of the bezel, and improves the appearance of the display device.

In another specific implementation of the present application, in order to bend the aluminum extruded profile more smoothly, the bending mold bends the aluminum extruded profile from 180 degrees to 90 degrees through N bending angles in order, the N bending angles being less than 180 degrees and greater than 90 degrees.

The N may be selected by a person skilled in the art according to requirements, and the bending angles gradually approach 90 degrees from 180 degrees.

Specifically, the N is two, and the bending angles include a first bending angle and a second bending angle.

The first bending angle is 150 degrees, and the second bending angle is 120 degrees.

Referring to FIG. 4a, an area A of the aluminum extruded profile is heated.

Referring to FIG. 4b, an area B of the aluminum extruded profile is heated, a crack arrest groove 41 is slotted at the rear of the aluminum extruded profile, and a bending angle of the aluminum extruded profile is made to be 140 degrees by using the bending mold.

Referring to FIG. 4c, an area C of the aluminum extruded profile is heated, and the bending angle of the aluminum extruded profile is made to be 120 degrees by using the bending mold.

Referring to FIG. 4d, an area D of the aluminum extruded profile is heated, and the bending angle of the aluminum extruded profile is made to be 90 degrees by using the bending mold.

Corresponding to the bezel of the display device, an embodiment of the present application further provides a method for manufacturing the bezel of the display device; referring to FIG. 1, the bezel 1 of the present application is used to fix the display module 2 of the display device.

Referring to FIG. 5, the method includes:

S1: softening an aluminum extruded profile with a U-shaped cross-section under a high temperature; and

S2: bending the aluminum extruded profile with a U-shaped cross-section using a bending mold to form a 90-degree bezel without gaps at front and rear surfaces.

The bezel of the display device manufactured according to the present application keeps the appearance of display device being impaired by gaps at the front and rear surfaces of the bezel, and improves the appearance of the display device.

In another specific implementation of the present application, in order to bend the aluminum extruded profile more smoothly, the bending mold bends the aluminum extruded profile from 180 degrees to 90 degrees through N bending angles in order, the N bending angles being less than 180 degrees and greater than 90 degrees.

The N may be selected by a person skilled in the art according to requirements, and the bending angles gradually approach 90 degrees from 180 degrees.

Specifically the N is two, and the bending angles include a first bending angle and a second bending angle.

The first bending angle is 150 degrees, and the second bending angle is 120 degrees.

Referring to FIG. 4a, an area A of the aluminum extruded profile is heated.

Referring to FIG. 4b, an area B of the aluminum extruded profile is heated, a crack arrest groove 41 is slotted at the rear of the aluminum extruded profile, and a bending angle of the aluminum extruded profile is made to be 140 degrees by using the bending mold.

Referring to FIG. 4c, an area C of the aluminum extruded profile is heated, and the bending angle of the aluminum extruded profile is made to be 120 degrees by using the bending mold.

Referring to FIG. 4d, an area D of the aluminum extruded profile is heated, and the bending angle of the aluminum extruded profile is made to be 90 degrees by using the bending mold.

The following further describes an implementation of the present application with reference to a specific application scenario.

Referring to FIG. 4a, an aluminum extruded profile with a U-shaped cross-section is used, and an area A of the aluminum extruded profile is heated.

Referring to FIG. 4b, an area B of the aluminum extruded profile is heated. A bending angle of the aluminum extruded profile is made to be 140 degrees by using a bending mold.

Referring to FIG. 4c, an area C of the aluminum extruded profile is heated, and the bending angle of the aluminum extruded profile is made to be 120 degrees by using the bending mold.

Referring to FIG. 4d, an area D of the aluminum extruded profile is heated, and the bending angle of the aluminum extruded profile is made to be 90 degrees by using the bending mold.

The bezel made by the aluminum extruded profile has no gaps at front and rear surfaces, and has a crack arrest groove at the rear surface. The bezel is used to fix a display module of the display device. The bezel of the display device manufactured according to the present application keeps the appearance of display device being impaired by gaps at the front and rear surfaces of the bezel, and improves the appearance of the display device.

Although preferred embodiments are described, those skilled in the art may make modifications and variations to these embodiments based on the basic inventive concept of the present application. Therefore, the preferred embodiments and all such modifications and variations shall fall within the protection scope of the present application. Apparently, a person skilled in the art may make various modifications and variations to the present application without departing from the spirit and principles of the present application. If such modifications and variations fall within the scope defined by the claims of the present application and equivalent technologies thereof, the present application is intended to cover such modifications and variations.

What is claimed is:

1. A bezel of a display device, the bezel being used to fix a display module of the display device, wherein
the bezel is a 90-degree bezel without gaps at front and rear surfaces, which is formed by an aluminum extruded profile with a U-shaped cross-section which is softened under a high temperature and bent by using a bending mold.

2. The bezel according to claim 1, wherein the bending mold bends the aluminum extruded profile from 180 degrees to 90 degrees through N bending angles in order, the N bending angles being less than 180 degrees and greater than 90 degrees.

3. The bezel according to claim 2, wherein the N is two, and the bending angles comprise a first bending angle and a second bending angle.

4. The bezel according to claim 3, wherein the first bending angle is 150 degrees, and the second bending angle is 120 degrees.

5. A display device, comprising a bezel and a display module, and the bezel being used to fix the display module, wherein
the bezel is a 90-degree bezel without gaps at front and rear surfaces, which is formed by an aluminum extruded profile with a U-shaped cross-section which is softened under a high temperature and bent by using a bending mold.

6. The display device according to claim 5, wherein the bending mold bends the aluminum extruded profile from 180 degrees to 90 degrees through N bending angles in order, the N bending angles being less than 180 degrees and greater than 90 degrees.

7. The display device according to claim 6, wherein the N is two, and the bending angles comprise a first bending angle and a second bending angle.

8. The display device according to claim 7, wherein the first bending angle is 150 degrees, and the second bending angle is 120 degrees.

9. A method for manufacturing a bezel of a display device, the bezel being used to fix a display module of the display device, comprising
softening an aluminum extruded profile with a U-shaped cross-section under a high temperature; and
bending the aluminum extruded profile with a U-shaped cross-section using a bending mold to form a 90-degree bezel without gaps at front and rear surfaces.

10. The manufacturing method according to claim 9, wherein the bending the aluminum extruded profile with a U-shaped cross-section using a bending mold to form a 90-degree bezel without gaps specifically comprises: bending, by the bending mold, the aluminum extruded profile from 180 degrees to 90 degrees through N bending angles in order, the N bending angles being less than 180 degrees and greater than 90 degrees.

11. The manufacturing method according to claim 10, wherein the N is two, and the bending angles comprise a first bending angle and a second bending angle.

12. The manufacturing method according to claim 11, wherein the first bending angle is 150 degrees, and the second bending angle is 120 degrees.
